(19) United States
(12) Patent Application Publication
(10) Pub. No.: US 2009/0274961 A1
(43) Pub. Date: Nov. 5, 2009

(54) Photosensitive composition for volume type hologram memory

(75) Inventors: Ken'ichi Koseki, Chiba-Shi (JP); Yohei Shoji, Chiba-Shi (JP); Hiroto Mitake, Himeji-Shi (JP)

Correspondence Address: BIRCH STEWART KOLASCH & BIRCH, PO BOX 747, FALLS CHURCH, VA, 22040-0747, US

(73) Assignee: DAICEL CHEMICAL INDUSTRIES, LTD., OSAKA (JP)

(21) Appl. No.: 11/991,357

(22) PCT Filed: Aug. 22, 2006
(86) PCT No.: PCT/JP2006/316354

§ 371 Date: Jul. 30, 2008

(30) Foreign Application Priority Data
Sep. 2, 2005 (JP) 2005-255677

(51) Int. Cl. G03F 7/00

(52) U.S. Cl. 430/2

(57) ABSTRACT

To provide photosensitive composition for volume type hologram memory with superior photosensitivity and large differences in reflective index before and after photo-curing and with controllable curing shrinkage. The photosensitive composition for volume type hologram memory of the present invention comprises a photo-curable volume expansion compound and a photoinitiator. According to the photosensitive composition for volume type hologram memory of the present invention, a composition of superior photosensitivity and large differences in reflective index before and after photo-curing and controllable curing shrinkage with photo-curable volume expansion composition can be provided.

### FIELD OF THE INVENTION

The present invention relates to a photosensitive composition for recording a volume type hologram (hereinafter called a photosensitive composition for volume type hologram memory), in particular, it relates to a volume type hologram recording photosensitive medium and a volume type hologram which are produced using the photosensitive composition.

### DESCRIPTION OF THE RELATED ART

A volume type hologram can represent an object in three dimensions, and it has an excellent diffraction efficiency and wavelength selectivity and requires a high level of manufacturing technology, therefore, it has been widely used in applications such as design, security and optical devices. This volume type hologram has a high level of coherence, and it is produced by interfering an object light and a reference light which have the same wavelength, irradiating the generated interference light to a material for volume type hologram and recording the three-dimensional data related to an object as an interference fringe within this material. This interference fringe is recorded as a refractive index modulation which corresponds to the light and dark parts of the interference light. In recent years, in the manufacture of volume type holograms, a photosensitive composition for volume type hologram memory which is a dry type and can be mass produced without a wet type developing process has been attracted attention.

Only DuPont's Omni decks series is marketed on a mass produced level as the dry type photosensitive composition stated above. This composition includes a radical photopolymerization monomer, a binder polymer, a radical photoinitiator and a sensitizing dye as the main ingredients, and utilizes the difference in the refractive index between the radical photopolymerization monomer and the binder polymer. That is, when the photosensitive composition which is formed into a film is subjected to interference exposure, a cross-linking reaction begins in parts where light is strong and a diffusion transfer of the polymerization monomer occurs. Consequently, the difference of density of the polymerization monomer is formed in accordance with the strength of the interference light, and the difference of the refraction index appears.

Alternatively, a volume type hologram recording composition having a high refraction index modulation and excellent transparency is disclosed in patent document 1 stated below. This material system includes as its main ingredients a monomer having a diallyl fluorene structure (or groups) as a radical polymerizable compound with a high refraction index, a cationic polymerizable compound and a binder resin.

In addition, in patent document 2 stated below, a composition consisting of a fluorene derivative oligomer having an epoxy group as a cationic polymerizable compound with a high refraction index, a polymerization monomer with a different refraction index from the oligomer, a photoinitiator and a sensitizer is disclosed. In this material system, the refraction index is increased because the epoxy oligomer takes on a cross-linked structure by cationic polymerization, and a hologram recording photosensitive medium with a strengthened refraction index modulation, excellent transparency and excellent heat resistance is obtained.

Furthermore, in patent document 3 stated below, a composition consisting of a fluorene derivative oligomer having an oxetanyl group as a cationic polymerizable compound with a high refraction index, a polymerization monomer with a different refraction index from the oligomer, a photoinitiator and a sensitizer is disclosed. In this material system, a cross-linked structure is obtained by a cationic polymerization caused by the high reactivity of the oxetanyl group and it is possible to obtain a recording hologram photosensitive medium with few shrinkages by curing, excellent transparency and heat resistance.

### Patent Document 1: Japanese Patent No. 2849021

### Patent Document 2: Japanese Patent No. 3075082

### Patent Document 3: Japanese Unexaminal Patent Application

### Publication (JP-A) No: 2004-138872

However, in the photosensitive composition for holograms disclosed in patent document 1 stated above, because a radical photopolymerizable group such as acrylate, methacrylate as a photopolymerizable functional group is used, the shrinkage which occurs with polymerization becomes an interruption when the photosensitive composition for holograms is applied in a memory or optical device which particularly requires dimensional stability. Furthermore, it is thought that DuPont's Omni decks series also has room for improvement in the similar issue described above while it is extremely useful in terms of being marketed on a mass produced level.

In addition, the photosensitive composition for holograms disclosed in the patent document 2 described above uses the fluorine derivative having an epoxy group as a cationic polymerizable composition and the epoxy group which is the photopolymerizable functional group. Therefore, there is a problem with sensitivity because the reactivity is low due to use of the glycidyl type epoxy group while the shrinkage in the radical polymerization is decreased.

In addition, in the photosensitive composition for holograms having an oxetanyl group disclosed in the patent document 3 stated above, there is a report where the problem of low sensitivity when using an epoxy group has been overcome by using an oxetanyl group which is a photopolymerizale function group having high reactivity, however, the problem of a reaction inhibition, that is oxygen inhibition, caused by oxygen included the oxetanyl group itself is remains in spite of cationic curing.

This invention attempts to solve the above stated problems, and an object of this invention is to provide a photosensitive composition for volume type hologram memory having excellent refractive index modulation, no change in volume around photo curing and the composition having excellent polymerization reactivity.

### BRIEF SUMMARY OF THE INVENTION

The inventors of the present invention performed a keen examination on the above stated problems, and then it is realized that the object of the present invention is accomplished by including a photo-curable volume expansion compound and a photoinitiator in a photosensitive composition for volume type hologram memory. Here, “a photo-curable volume expansion compound” is a compound which is polymerized by light and in which volume after polymerization compared with the volume before polymerization expands. Further, in this case, in accordance with necessity, it is useful to add in advance photopolymerizable compounds other than a photo-curable volume expansion compound, a binder resin and a sensitizing dye. In particular, adding photopolymerizable compound other than a photo-curable volume expansion compound is extremely useful because a volume change in the volume type hologram can be more easily controlled. Also in this case, when it is assumed that the total weight of a photosensitive composition for volume type hologram memory is 100 pts. wt., it is preferred that the amount of photo-curable volume expansion compound is between the range of 1˜90 pts. wt.

In addition, in the photosensitive composition for volume type hologram memory related to the present invention, it is preferred that the photo-curable volume expansion compound is represented by the following chemical formula (1). Further, the following compound is Ames-negative and is useful in that its toxicity can be kept low.

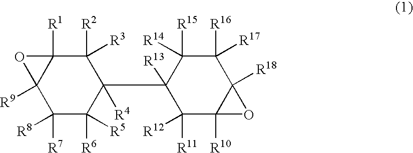

(In the chemical formula, R¹˜R¹⁸ are hydrogen atoms, halogen atoms, alkyl group or alkoxy group, in the case of alkyl group or alkoxy group, oxygen atoms or halogen atoms or a substituent group may be included. Also, R¹˜R¹⁸ may each be the same or different).

In addition, in the photosensitive composition for volume type hologram memory related to the present invention, it is preferred that the photo-curable volume expansion compound is represented by the following chemical formula (2).

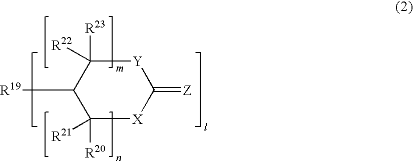

(In the expression, R²⁰˜R²³ are hydrogen atoms, halogen atoms, alkyl group or alkoxy group, in the case of alkyl group or alkoxy group, oxygen atoms or halogen atoms or a substituent group may be included. Also, R²⁰˜R²³ may each be the same or different. Here, l is an integer number between 1˜6, and m and n are integer numbers between 0˜3. And X, Y and Z are oxygen atoms or sulphur atoms. R¹⁹ represents hydrogen atoms, multifunctional alkyl, alkyl ester or alkyl ether.)

The photosensitive composition for volume type hologram memory related to the present invention described above can control curing shrinkage by including a compound having expansibility caused by photopolymerization within the system, and it is possible to obtain an ideal photosensitive medium for volume type hologram memory in which volume shrinkage hardly occur by its design.

In addition, the photosensitive composition for volume type hologram memory related to the present invention is dissolved in a solvent and made into a coating solution, and then the photosensitive medium for volume type hologram memory is obtained by coating the solution on a substrate film and drying it.

That is, the photosensitive medium for volume type hologram memory related to this invention includes a substrate film and a volume type hologram material layer which is arranged on this substrate film, and the volume type hologram material layer includes a photo-curable volume expansion compound and a photoinitiator. Also, in this case, adding in advance photopolymerizable compounds other than a photo-curable volume expansion compound, a binder resin and a sensitizing dye is preferred. Further, the photo-curable volume expansion compound in the volume type hologram material layer is preferred to be within the range of 1˜90 pts. wt. when it is assumed that the total weight of the volume type hologram material layer is 100 pts. wt.

In addition, in the photosensitive medium for volume type hologram memory, it is preferred that the photo-curable volume expansion compound in the volume type hologram material layer is represented by the following chemical formula (1).

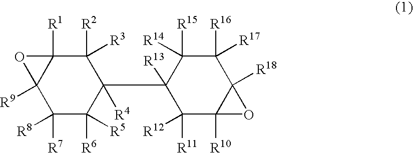

(In the chemical formula, R¹˜R¹⁸ are hydrogen atoms, halogen atoms, alkyl group or alkoxy group, in the case of alkyl group or alkoxy group, oxygen atoms or halogen atoms or a substituent group may be included. Also, R¹˜R¹⁸ may each be the same or different.)

Also, in the photosensitive medium for volume type hologram memory related to the present invention, it is preferred that the volume expansion compound in the volume type hologram material layer is represented by the following chemical formula (2).

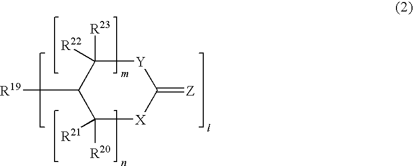

(In the chemical formula, R²⁰˜R²³ are hydrogen atoms, halogen atoms, alkyl group or alkoxy group, in the case of alkyl group or alkoxy group, oxygen atoms or halogen atoms or a substituent group may be included. Also, R²⁰˜R²³ may each be the same or different. Here, l is an integer number between 1˜6, and m and n are integer numbers between 0˜3. And, X, Y and Z are oxygen atoms or sulphur atoms. R¹⁹ represents hydrogen atoms, multifunctional alkyl in which the carbon number is within the range 1˜10, alkyl ester or alkyl ether.)

### BRIEF DESCRIPTION OF THE DRAWINGS

FIG. 1 is a drawing which shows a result in an embodiment and a comparative example.

### DETAILED DESCRIPTION OF THE INVENTION

Below, the photosensitive composition for volume type hologram memory, photosensitive medium for volume type hologram memory and volume type hologram will be further explained in detail.

The photosensitive composition for volume type hologram memory related to the present embodiment includes as an essential element at least the volume expansion compound expressed by chemical formula (1) or the volume expansion compound expressed by chemical formula (2) stated above and further contains other elements such as photopolymerizable compounds other than the above stated volume expansion compound, binder resins and sensitizing dyes. In this case, it is preferred that the above stated photopolymerizable compound shows cationic photopolymerizability. In addition, by using a photosensitive medium for volume type hologram memory which is produced by coating a photosensitive composition for volume type hologram memory which includes a photopolymerizable compound having the above stated volume expansion compound as a photopolymerizable compound on to a substrate material, it is possible to obtain a volume type hologram having an excellent capability to control curing shrinkage.

### <Cationic Photopolymerizable Compound>

A cationic photopolymerizable compound is a compound having a function group which shows cationic photopolymerizability. There are many known function groups which show cationic photopolymerizability, however, such groups as epoxy group, vinyl group and oxetanyl group are widely known particularly for their high level of practicality.

A compound having an epoxy group is not particularly limited as long as the compound has an epoxy group, for example, it is possible to preferably use an alicyclic epoxy resin. As an example of an alicyclic epoxy resin, it is possible to preferably use CELLOXIDE 2000, 2021, 3000, EHPE3150CE manufactured by DAICEL CHEMICAL INDUSTRIES, LTD, epomicVG-3101 manufactured by MITSUI PETROCHEMICAL INDUSTRIES LTD, E-1031S manufactured by YUKASHELL EPOXY LTD, TETRAD-X, TETRAD-C manufactured by MITSUBISHI GAS CHEMICAL CO. LTD, EPB-13, EPB-27 manufactured by NIPPON SODA CO. LTD. In addition, as another example of a compound having an epoxy group, it is also possible to use a hybrid compound having an epoxy group and (metha)acrylate group. As an example of this compound, there are, for example, 3,4-epoxy cyclohexylmethyl (metha)acrylate, glycidyl methacrylate and vinyl glycidyl ether etc. Further, these can be used alone or used in combination.

A compound having a vinyl group, is not particularly limited as long as the compound has a vinyl group, for example, it is possible to preferably use as a commercial product, 2-hydroxy ethyl vinyl ether (HEVE), diethylene glycol monovinyl ether (DEGV), 2-hydroxy butyl vinyl ether (HBVE), triethylene glycol divinyl ether manufactured by MARUZEN PETROCHEMICAL CO. LTD, RAPI-CURE SERIES manufactured by ISP CO. LTD, V-PYROL (Registered Trademark) (N-Viny-2-Pyrrolidone) and V-CAPTM (N-Vinyl-2-Caprolactam) etc. In addition, it is also possible to use a vinyl compound having a substituent group such as alkyl or alyl group etc. at α and/or β position. Further, these can be used alone or in combination.

A compound having a oxetanyl group is not particularly limited as long as the compound has a oxetanyl group, for example, it is possible to preferably use as a commercial product, 3-ethyl-3-(phenoxymethyl)oxetane (POX), di[1-ethyl(3-oxetanyl)]methyl ether (DOX), 3-ethyl-3-(2-ethylhexyloxymethyl)oxetane (EHOX),3-ethyl-3-{[3-(triethoxysilyl)propoxy]methyl}oxetane (TESOX), oxetanyl silsesquioxane (OX-SQ) and phenol novolac oxetane (PNOX-1009) etc. In addition, it is also possible to use a hybrid compound having an oxetanyl group and (metha)acryl group. These can be used alone or in combination.

In addition, in this photosensitive composition for volume type hologram memory, curing shrinkage can be controlled by adding a volume expansion compound, and a hologram composition having good reproducibility can also be obtained.

Because the volume expansion compound can be appropriately design as long as it can control the volume change of the photosensitive composition for volume type hologram memory before and after polymerization, there is no particular amount limit, however, when it is assumed that the total weight of the photosensitive composition for volume type hologram memory (the total weight is the total weight of the photo-curable volume expansion compound and the photoinitiator, and in the case where other photopolymerizable compounds, a binder resin and a sensitizing dye are added, the total weight of the photosensitive composition for volume type hologram memory is the total weight of the photo-curable volume expansion compound, the photoinitiator, the other photopolymerization compounds, the binder resin and the sensitizing dye.) is 100 pts. wt., it is preferred that volume expansion compound is between 1˜90 pts. wt.

### <Binder Resin>

There is no particular restriction to a binder resin to be used in this photosensitive composition for volume type hologram memory, for example, copolymer includes as polymerization component at least one of a monomer group which can be copolymerized such as poly(metha)acrylic acid ester or that hydrolysate, polyvinyl acetate or that hydrolysate, polyvinyl alcohol or that part acetal compound, triacetyl cellos, polyisoprene, polybutadiene, polychloroprene, silicongum, polystyrene, polyvinyl butyral, polychloroprene, polyvinylchloride, polyallirate, chlorinated polyethylene, chlorinated polypropylene, poly-N-vinylcarbazole or that derivative, poly-N-vinylpyrrolidone or that derivative, polyallirate, copolymer of styrene and anhydrous maleic acid or that half ester, acrylic acid, acrylic acid ester, methacrylic acid, methacrylic acid ester, acrylamide, acrylonitrile, ethylene, propylene, vinyl chloride, vinyl acetate, or a mixture of these can be preferably used as the binder resin.

In addition, an olygomer type curable resin can also be used as the binder resin. For example, there is an epoxy resin having unsaturated groups such as epoxy polybutadiene, epoxy butadienestyrenebloc copolymer etc. As a commercial product, EPOLEAD PB manufactured by DAICEL CHEMICAL INDUSTRIES, LTD., EPOFRIEND series (epoxySBS) manufactured by DAICEL CHEMICAL INDUSTRIES, LTD., CP-50M, CP-50S which are a copolymer of glycidyl methacrylate and styrene and a copolymer of glycidyl methacrylate, styrene and methyl methacrylate manufactured by NOF CORPORATION or a copolymer such as glycidyl methacrylate and cyclohexyl maleimide.

In addition, other epoxy resins which have a unique structure apart from those stated above, for example, the CELLTOP which is a copolymer of 3,4-epoxy cyclohexylmethyl(metha)acrylate and stylene or a copolymer of 3,4-epoxy cyclohexylmethyl(metha)acrylate, stylene and methyl methacrylate manufactured by DAICEL CHEMICAL INDUSTRIES, LTD etc. can also be preferably used as binder resins.

Furthermore, as a binder resin, novolac type epoxy resin (For example, a product obtained by a reaction of novolacs which are obtained by reacting of phenols such as phenol. cresol, halogenated phenol and alkyl phenol with formaldehyde under an acidic catalyst and epichlorohydrin and/or methyl epichlorohydrin. As the commercial product, there are EOCN-103, EOCN-104S, EOCN-1020, EOCN-1027, EPPN-201, BREN-S manufactured by NIPPON KAYAKU CO., LTD., DEN-431, DEN-439 manufactured by DOW CHEMICAL LTD. and N-73, VH-4150 manufactured by DAINIPPON INK AND CHEMNICALS INC.), bisphenol type epoxy resin (For example, a product obtained by a reaction of bisphenols such as bisphenol A, bisphenol F, bisphenol S and tetrabromo bisphenol A with epichlorohydrin, and obtained by a reaction diglycidyl ether of bisphenol A and the bisphenols. As the commercial product, there are Epikote 1004, Epikote 1002 manufactured by YUKA SHELL LTD. and DER-330, DER-337 manufactured by DOW CHEMICAL CO., LTD) and compound obtained by reacting trisphenol methane or triscresol methane etc. and epichlorohydrin and/or methyl epichlorohydrin etc., as a commercial product, EPPN-501, EPPN-502, tris (2,3-epichlorohydrin) isocyanurate, biphenyl diglycidyl ether, can be preferably used. These epoxy resins may be used alone or in combination.

Furthermore, each of the above stated binder resins can be preferably used, however, in the case of using a monomer transfer process by heating, which is a stabilization process of the recorded hologram, it is even more preferable for these binder resins to be able to easily perform a monomer transfer in which their glass transition temperatures are relatively low.

In addition, it is possible to use an organic-inorganic hybrid resin which utilizes a sol-gel reaction as a binder resin. A copolymer of a vinyl monomer and an organic metal compound having a polymerizable group represented by the following chemical formula (3) is given as one example of an organic-inorganic hybrid polymer.

RₘM(OR′)ₙ (3)

(in the chemical formula, M expresses a metal such as Si, Ti, Zr, Zn, In, Sn, Al and Se etc., R expresses a vinyl group or (metha)acryloyl group with a carbon number between 1˜10, R′ expresses an alkyl group with a carbon number between 1˜10 and m+n expresses the valence number of the metal M).

Furthermore, vinyl triethoxysilane, vinyl trimethoxysilane, vinyl tributoxysilane, vinyl triallyloxysilane, vinyl tetraethoxysilane, vinyl tetramethoxysilane, acryloxypropyltrimethoxysilane, and methacryloxypropyltrimethoxysilane etc. are example compounds in the case where Si is used as the metal in the above chemical formula (3).

In addition, while acrylic acid, acrylic acid ester, methacrylic acid and methacrylic acid esters etc. are given as examples of a vinyl monomer stated above, they are not limited to these.

Furthermore, in order to improve the refractive index difference between a binder resin and a photopolymerizable compound, it is possible to add an organic metal compound within the present photosensitive composition for volume type hologram memory represented in the following chemical formula (4).

M′(OR″)_{n′} (4)

(In the chemical formula, M expresses a metal such as Si, Ti, Zr, Zn, In, Sn, Al and Se etc., R″ expresses a alIkyl group with a carbon number between 1˜10 and n′expresses the valence number of the metal M.)

Furthermore, when the above stated compound is added to the above stated binder resin, because the binder resin and this compound form a mesh structure by a sol-gel reaction in the presence of water and an acid catalyst, the refractive index of the binder resin is not only raised but the strength and heat resistance of the film are also improved. In order to increase the refractive index difference between the binder resin and the photopolymerizable compound, it is preferred that the metal (M′) may be selected so that the binder resin has high refractive index as possible.

As a preferred embodiment of the present hologram recording photosensitive composition, it is also possible that a photopolymerizable compound other than cationic photopolymerizable compound is added. As another photopolymerizable compound, for example, it is possible to suggest a radical photopolymerizable compound, and a compound having at least one ethylene unsaturated double bond which can additional polymerize can be adduced as this example. As a more specific example, unsaturated carboxylic acid and its salt, an ester of an unsaturated carboxylic acid and an aliphatic multiple alcohol compound, and a compound having an amide bond of an unsaturated carboxylic acid and an aliphatic multiple amine compound etc. are suggested.

As examples of an ester of an unsaturated carboxylic acid and an aliphatic multiple alcohol compound, acrylic acid ester and methacrylic acid ester are suggested. As specific examples of an acrylic acid ester, ethylene glycol diacrylate, triethylene glycol diacrylate, 1,3-butanediol diacrylate, tetramethylene glycol diacrylate, propylene glycol diacrylate, neopenthyl glycol diacrylate, trimethylolpropane triacrylate, trimethylolpropane tri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetracrylate, dipentaerythritol diacrylate, dipentaerythritol triacrylate, dipentaerythritol tetracrylate, dipentaerythritol hexacrylate, sorbitol triacrylate, sorbitol tetracrylate, sorbitol pentacrylate, sorbitol hexacrylate, tri(acryloyloxyethyl)isocyanurate, polyesteracrylateoligomer, 2-phenoxyethylacrylate, phenolethoxylatemonoacrylate, 2-(p-chlorophenoxy)ethylacrylate, p-chlorophenylacrylate, phenylacrylate, 2-phenylethylacrylate, [(2-acryloxyethyl)ether] of bisphenolA, ethoxylated bisphenoiAdiacrylate, [2-(1-naphthyloxy)ethylacrylate], o-biphenylacrylate, 9,9-bis(4-acryloxydiethoxyphenyl)fluorene, 9,9-bis(4-acryloxytriethoxyphenyl)fluorene, 9,9-bis(4-acryloxydipropoxyphenyl)fluorene, 9,9-bis(4-acryloxyethoxy-3-methylphenyl)fluorene, 9,9-bis(4-acryloxyethoxy-3-ethylphenyl)fluorene, and 9,9-bis(4-acryloxyethoxy-3,5-dimethyl)fluorene etc. are suggested. Furthermore, “acrylate” in the above compound names becomes “methacrylate”, “acryloxy” becomes “methacryloxy” and “acryloyl” becomes “methacryloyl” among the above stated acrylic acid esters are given as a specific example of methacrylic acid ester.

In addition, it is also possible to use an acrylic compound having containing sulphur which is disclosed in Japanese Unexaminal Patent Application Publication No. S61-72748, for example, 4,4′-bis(β-acryloyloxyethylthio)diphenylsulfone, 4,4′-bis(β-acryloyloxyethylthio)diphenylketone, 4,4′-bis(β-acryloyloxyethylthio)-3,3′,5,5′-tetrabromodiphenylketone, 2,4-bis(β-acryloyloxyethylthio)diphenylketone, are suggested, however, they are not limited to these.

### <Photoinitiator>

The following can be preferably used as a cationic photoinitiator (photo acid generator) in the case of using the compounds which can cationic photopolymerize but not limited to these: aromatic diazonium salt, aromatic iodonium salt, aromatic sulfonium salt, aromatic phosphonium salt, mixed ligand metal salt, (η6-benzene)(η5-cyclopentadienyl)iron(+2), and silanol-aluminum complex etc.

In addition, the following can be preferably used as a radical photoinitiator in the case of using the compounds which have radical photopolymerization characteristics but not limited to these: 1,3-di(t-butyldioxycarbonyl)benzophenone, 3,3′,4,4′-tetrakis(t-butyldioxycarbonyl)benzophenone, N-phenylglycine, 2,4,6-tris(trichloromethyl)-s-triazine, 3-phenyl-5-isoxazolone, 2-mercaptobenzimidazole and imidazole dimmer etc.

Furthermore, in the case of a so called hybrid type material which combines use of radical photopolymerization and cationic photopolymerization, it is possible to combine and use each of the above photoinitiators respectively, and it is possible to use a photoinitiator which has a function which initiates both polymerizations in one variety of initiator. As a photoinitiator which has a function which initiates both polymerizations in one variety of initiator, aromatic iodonium salt and aromatic sulfonium salt etc. can be preferably used but are not limited to these.

Furthermore, it is preferred that the photoinitiator is decomposed after hologram recording from the viewpoint of the stability of the recorded hologram. In addition, it is preferred that the amount of added photoinitiator is within the range of 0.1 to 30 pts. wt. when each of the curable substrates of a photo cation and a photo radical are 100 pts. wt. respectively, and more preferably within the range of 1 to 20 pts. wt., and between 1 and 10 pts. wt. when a photo cation is a curable substrate.

### <Sensitizing Dye>

A sensitizing dye which is added according to necessity in order to amplify photosensitive capabilities at the time of recording a hologram preferably may use the following as sensitizing dyes but not limited to these: thiopyrylium salt dye, merocyanine dye, quinoline dye, styrylquinoline dye, chaetoqumarine dye, thioxanthen dye, xanthen dye, oxonol dye, cyanine dye, rhodamine dye and pyrylium dye etc.

Furthermore, in the case where a high degree of transparency is demanded, for example, in a hologram for optical devices, the sensitizing dye is preferably decomposed by heating or ultraviolet light irradiation in post processing after hologram recording and it is preferred that the sensitizing dye become colorless in the wavelength region of light (for example, visible light region) that is used. In addition, the amount of sensitizing dye which is added is preferably in the range of 0.1 to 100 pts. wt. when the photoinitiator is 100 pts. wt. and more preferably in the range of 0.01 to 30 Pts. wt.

### <Photosensitive Medium for Volume Type Hologram Memory>

Next, the present photosensitive medium for volume type hologram memory will be explained. The present photosensitive medium for volume type hologram memory can be obtained by producing a coating solution by dissolving the photosensitive composition for volume type hologram memory described above in a solvent, coating the coating solution onto a substrate and drying the coated substrate.

The following examples can be preferably used alone or as a combined solvent as the above stated solvent as long as the solvent can dissolve the photosensitive composition for volume type hologram memory, but are not limited to these: acetone, methylethylketone, methylisobutylketone, cyclohexanone, benzene, toluene, xylene, chlorobenzene, tetrahydrofuran, methyl cellosolve, ethyl cellosolve, methyl cellosolve acetate, ethyl cellosolve acetate, ethyl acetate, 1,4-dioxane, 1,2-dichloroethane, dichloromethane, chloroform, methanol, ethanol and isopropanol etc.

A material having transparency may be used as a substrate film which is coated with the coating solution, for example, the following can be preferably used but are not limited to these: polyethylene film, polypropylene film, polyethylene fluoride film, polyvinylidene fluoride film, polyvinyl chloride film, polyvinylidene chloride film, ethylene-vinylalcohol film, polyvinyl alcohol film, polymethyl methacrylate film, polyethersulfone film, polyether ether ketone film, polyamide film, tetrafluoroethylene-perfluoroalkylvinylether copolymer film, polyester film such as polyethyleneterephthalate film, and polyimide film etc.

In addition, in the present photosensitive medium for volume type hologram memory, it is preferable that the thickness of volume type hologram material which is obtained by drying or dissolving a coating solution is in the range of 1 to 100 μm, and more preferably in the range of 5 to 40 μm. Consequently, it is preferred that the thickness of the coating solution which is coated upon the substrate film is adjusted appropriately in view of the thickness of volume type hologram material. In addition, the thickness of the substrate film, which is not particularly limited, is in the range of 2 to 20 μm preferably from the viewpoint of securing transparency, and more preferably within the range of 10 to 50 μm.

It is possible to use conventional technology as a method for coating the above stated coating solution upon a substrate, for example, spin coater, gravure coater, comma coater and bar coater methods etc. can be used. In addition, in the case of a coating solution with a low degree of viscosity, it is possible to produce a photosensitive medium for volume type hologram memory by inserting a coating solution between one pair of substrates (for example glass substrates) and sealing the periphery of this pair of substrates.

In addition, in the case where a material layer of a volume type hologram after drying is adhesive, other than the method of inserting the coating solution between the above stated pair of substrates, it is preferable to laminate the substrate film and volume type hologram material layer with a protective film. Furthermore, in this case, it is extremely useful to perform a releasing process to the contact surface between the protective film and the volume type hologram material layer in advance so that they are easy to separate.

It is possible to use various methods which is known in the prior technology as a method for recording a hologram to the present photosensitive medium for volume type hologram memory, however, it is not limited to this, for example, it is possible to preferably use a method for recording a volume type hologram by attaching an original plate firmly to the volume type hologram material layer of the photosensitive medium for volume type hologram memory firstly and performing an interference exposure using a visible light, ultraviolet light or ionization radiation such as electron beam from the side of the transparent substrate film. In addition, in the case where the medium is inserted between glasses or films, a method for recording by attaching the original plate and the glass or film via an index matching fluid therebetween, irradiating laser light to the volume type hologram material layer from the side opposite to the original plate, and using the interference between the irradiated laser light and the laser light which is reflected from the original plate, a method for recording by dividing laser light in two directions, irradiating the divided one to the volume type hologram material layer and the other one to the object to be recorded, and using the interference between the light reflected from the object and the directly irradiated light, and a method for recording generally called the collinear method in which a data light and a reference light are irradiated from the same direction and recorded as interference light in the volume direction.

Furthermore, it is possible to preferably use laser light which is emitted from, for example, a visible laser (for example, an argon ion laser (458 nm, 488 nm, 514.5 nm), a krypton ion laser (647.1 nm), a helium-neon ion laser (633 nm), a YAG laser (532 nm) and a semiconductor laser (405 nm)) etc. as a light which is used in the above stated hologram recording. In addition, it is also preferred to appropriately perform entire surface exposure by ultraviolet or heating treatment after interference exposure in order to promote the refraction-index modulation and to complete polymerization reaction.

The hologram recording mechanism which is used the present photosensitive composition for volume type hologram memory is explained below. That is, when the present photosensitive composition which is formed in the form of a film is interfered and exposed by a laser, cationic photopolymerization begins in the part where the light is strong and a concentration gradient of the cationic photopolymerizable compound is formed with the photopolymerization, and a diffusion of the present cationic photopolymerizable compound occurs from the part where the light is weak to the part where the light is strong. As a result, in accordance with the strength of the interference light, a difference of the density of the cationic photopolymerizable compound is made and because the difference of the density appears as a difference in the refraction-index, it becomes possible to record a hologram.

In addition, in the case where a binder resin is included in the photosensitive composition for volume type hologram memory, it is possible to record a hologram by the difference in the refractive index between the cationic photopolymerizable compound and the binder resin. It is possible to promote the refractive-index modulation by heating after the interference exposure by a laser regardless of the presence of a binder resin, however, particularly in the case where a binder resin is included, by setting the heating temperature around the glass transition temperature of the binder resin, it is possible to promote a monomer transfer efficiently and increase the amount of refractive-index modulation (Δn).

Hereinafter, a volume type hologram using a hologram recording photosensitive composition in the above stated embodiments is produced actually, and verification of the effects of the hologram is performed. The following is the explanation.

### Example 1

A volume hologram recording photosensitive composition coating solution of the composition stated below was prepared and formed into a film by a spincoat method so that the film thickness becomes 20 μm after drying on a glass substrate with dimensions 76×52 mm and 1.3 mm thick, and a volume hologram recording photosensitive medium was produced after cyclohexanone was sufficiently evaporated.

polystyrene resin 43 pts. wt.
compound of the following chemical structural formula (5) (hereinafter called as “EBP”) 50 pts. wt.
3,4-epoxycyclohexylmethyl-3,4-epoxycyclohexanecarboxylate (CELLOXIDE2021 P: manufactured by DAICELL CHEMICAL INDUSTRIES) 50 pts. wt.
diaryliodonium salt (PI2074: manufactured by Rhodia) 5 pts. wt. 3,3′-carbonylbis[7-(diethylamino)coumarin] 0.15 pts. wt. cyclohexanone 172 pts. wt.

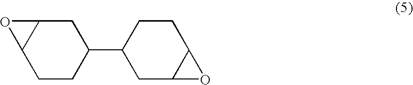

Next, a volume type hologram was recorded by irradiating an object light and a reference light to the obtained photosensitive medium for volume type hologram memory (dry plate) using a 488 nm argon ion laser with both at 45° angle. Then, a photosensitive composition was solidified by heating and an immobile volume type hologram was obtained.

Then, the transmittance of the obtained volume type hologram was measured using a spectrophotometer (manufactured by JASCO Corporation V-500), and a diffraction efficiency and volume contractility were calculated. When a compound in which the weight ratio is 50 to an alicyclic epoxide was inspected, the diffraction efficiency in an amount of light exposure of 30 mJ/cm² was 18.8% and the shrinkage after recording was 0.41%.

### Example 2

A volume type hologram was produced as in example 1 except that the compound (5) was given as 100 pts. wt. and 3,4-epoxycyclohexylmethyl-3,4-epoxycyclohexanecarboxylate was given as 0 pts. wt. (not added). And when a spectrophotometer transmittance measurement was performed as in example 1, the diffraction efficiency in an amount of light exposure of 30 mJ/cm² was 15.7% and the volume expansion coefficient after recording was 1.64%.

### Comparative Example

A volume hologram recording photosensitive composition coating solution of the composition stated below was prepared and a volume hologram recording photosensitive medium was obtained as in example 1.

polystyrene resin 43 pts. wt.
3,4-epoxycyclohexylmethyl-3,4-epoxycyclohexanecarboxylate (CELLOXIDE2021P: manufactured by DAICELL CHEMICAL INDUSTRIES) 100 pts. wt.
diaryliodonium salt (PI2074: manufactured by Rhodia) 5 pts. wt. 3,3′-carbonylbis[7-(diethylamino)coumarin] 0.15 pts. wt. cyclohexanone 172 pts. wt.

In addition, as the result of measuring diffraction efficiency and shrinkage using the same method as in example 1, diffraction efficiency was 17.3% after recording in an amount of light exposure of 30 mJ/cm² and shrinkage was 2.46%.

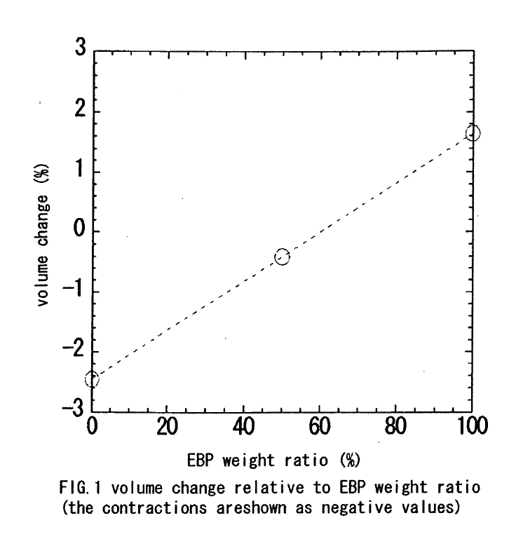

Furthermore, the results of example 1, example 2 and comparative example 1 are shown in the following table 1 and FIG. 1. These results confirmed that it is possible to sufficiently control a volume change and ideally to set the volume change to almost 0 by adding a photo-curable volume expansion compound to the photosensitive composition for volume type hologram memory according to example 1.

TABLE 1
EBP weight ratio and volume change (the contraction is negative)

| | comparative | | |
|---|---|---|---|
| | example 1 | example 1 | example 2 |
| EBP weight ratio | 0 | 50 | 100 |
| diffraction efficiency (%) | 17.3 | 18.8 | 15.7 |
| volume change (%) | −2.46 | −0.41 | 1.64 |

### Example 3

A photosensitive composition coating solution for volume type hologram memory having the composition stated below was prepared and a volume hologram recording photosensitive medium was obtained as in example 1. The diffraction efficiency and shrinkage using the same method as in example 1 was measured. As the result of the measurement, diffraction efficiency was 17.3% and shrinkage was 0.74%.

polystyrene resin 43 pts. wt.
compound of the following chemical structural formula (6) 25 pts. wt. 3,4-epoxycyclohexylmethyl-3,4-epoxycyclohexanecarboxylate (CELLOXIDE2021P: manufactured by DAICELL CHEMICAL INDUSTRIES) 100 pts. wt.
diaryliodonium salt (PI2074: manufactured by Rhodia) 5 pts. wt. 3,3′-carbonylbis[7-(diethylamino)coumarin] 0.15 pts. wt. cyclohexanone 172 pts. wt.

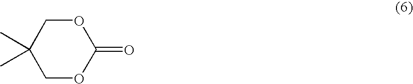

### Comparative Example 2

### Comparison with a Radical Polymerization Group

A photosensitive composition coating solution for volume type hologram memory having the composition stated below was prepared and a photosensitive medium for volume type hologram memory was obtained by inserting the photosensitive composition coating solution for volume type hologram memory between two glass plates in which a 25 μm PET film spacers are inserted therebetween. The diffraction efficiency and shrinkage was measured using the same method as in example 1. The diffraction efficiency was 29.8% in an amount of light exposure of 30 mJ/cm² and shrinkage was 10.2%.

pentaerythritoltriacrylate 70 pts. wt.
neopentylglycoldimethacrylate 30 pts. wt. 3,3′,4,4′-tetrakis(t-butylperoxycarbonyl)benzophenone 5 pts. wt. 3,3′-carbonylbis[7-(diethylamino)coumarin] 0.15 pts. wt. diethylsebacate 20 pts. wt.

According to the invention, it is possible to obtain a photosensitive composition for volume type hologram memory which can sufficiently reduce curing shrinkage by including a volume expansion compound. Furthermore, by using this, it is possible to obtain an excellent photosensitive medium for volume type hologram memory and a volume type hologram.

The present invention relates to a photosensitive composition for volume type hologram memory as above, and has an industrial applicability which can realize a photosensitive medium for volume type hologram memory and volume type hologram using this photosensitive composition for volume type hologram memory.

1. A volume type hologram recording photosensitive composition comprising;
a photo-curable volume expansion compound, and
a photoinitiator.

2. The volume type hologram recording photosensitive composition according to claim 1, further including a photopolymerization compound other than said photo-curable volume expansion compound.

3. The volume type hologram recording photosensitive composition according to claim 1, wherein said volume expansion compound is represented by the following chemical formula (1). 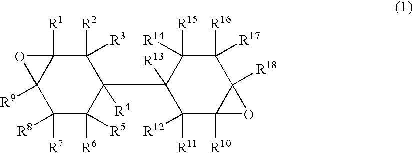
(In the chemical formula, R¹˜R¹⁸ are hydrogen atoms, halogen atoms, alkyl group or alkoxy group, in the case of alkyl group or alkoxy group, oxygen atoms or halogen atoms or a substituent group may be included. Also, R¹˜R¹⁸ may each be the same or different.)

4. The volume type hologram recording photosensitive composition according to claim 1, wherein said volume expansion compound is represented by the following chemical formula (1). 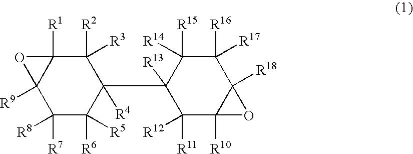
(In the chemical formula, R¹˜R¹⁸ are hydrogen atoms, halogen atoms, alkyl group or alkoxy group, in the case of alkyl group or alkoxy group, oxygen atoms or halogen atoms or a substituent group may be included. Also, R¹˜R¹⁸ may each be the same or different.)

5. The volume type hologram recording photosensitive composition according to claim 1, wherein said volume expansion compound is represented by the following chemical formula (2). 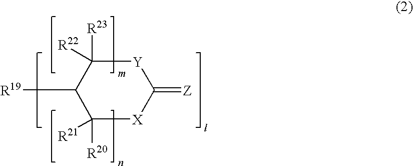
(In the expression, R²⁰˜R²³ are hydrogen atoms, halogen atoms, alkyl group or alkoxy group, in the case of alkyl group or alkoxy group, oxygen atoms or halogen atoms or a substituent group may be included. Also, R²⁰˜R²³ may each be the same or different. l is an integer number between 1˜6, m and n are integer numbers between 0˜3. X, Y and Z are oxygen atoms or sulphur atoms. R¹⁹ represents hydrogen atoms, polyfunctional alkyl in which the carbon number is 1˜10, alkyl ester or alkyl ether.)

6. The volume type hologram recording photosensitive composition according to claim 2, wherein said volume expansion compound is represented by the following chemical formula (2). 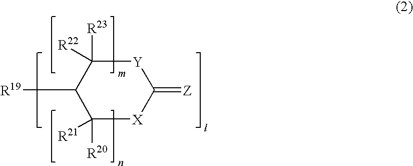
(In the chemical formula, R²⁰˜R²³ are hydrogen atoms, halogen atoms, alkyl group or alkoxy group, in the case of alkyl group or alkoxy group, oxygen atoms or halogen atoms or a substituent group may be included. Also, R²⁰˜R²³ may each be the same or different. l is an integer number between 1˜6, m and n are integer numbers between 0˜3. X, Y and Z are oxygen atoms or sulphur atoms. R¹⁹ represents hydrogen atoms, polyfunctional alkyl in which the carbon number is 1˜10, alkyl ester or alkyl ether.)

7. The volume type hologram recording photosensitive composition according to claim 1, further including a binder resin.

8. The volume type hologram recording photosensitive composition according to claim 2, further including a binder resin.

9. The volume type hologram recording photosensitive composition according to claim 3, further including a binder resin.

10. The volume type hologram recording photosensitive composition according to claim 4, further including a binder resin.

11. The volume type hologram recording photosensitive composition according to claim 5, further including a binder resin.

12. The volume type hologram recording photosensitive composition according to claim 6, further including a binder resin.

13. The volume type hologram recording photosensitive composition according to claim 1, further including a sensitizing dye.

14. The volume type hologram recording photosensitive composition according to claim 2, further including a sensitizing dye.

15. The volume type hologram recording photosensitive composition according to claim 3, further including a sensitizing dye.

16. The volume type hologram recording photosensitive composition according to claim 4, further including a sensitizing dye.

17. The volume type hologram recording photosensitive composition according to claim 5, further including a sensitizing dye.

18. The volume type hologram recording photosensitive composition according to claim 6, further including a sensitizing dye.

19. The volume type hologram recording photosensitive composition according to claim 7, further including a sensitizing dye.

20. The volume type hologram recording photosensitive composition according to claim 8, further including a sensitizing dye.

21. The volume type hologram recording photosensitive composition according to claim 9, further including a sensitizing dye.

22. The volume type hologram recording photosensitive composition according to claim 10, further including a sensitizing dye.

23. The volume type hologram recording photosensitive composition recording according to claim 11, further including a sensitizing dye.

24. The volume type hologram recording photosensitive composition volume type hologram recording according to claim 12, further including a sensitizing dye.

25. The volume type hologram recording photosensitive composition according to claim 1, wherein said volume expansion compound is included at 1 to 90 pts. wt. in the case where the total weight of said volume type hologram recording photosensitive composition is 100 pts. wt.

26. A volume type hologram recording photosensitive medium comprising;
a substrate film, and
a volume type hologram material layer arranged on said substrate film, wherein said volume type hologram material layer includes a photo-curable volume expansion compound and a photoinitiator.

27. The volume type hologram recording photosensitive medium recording according to claim 26, further including a photopolymerization compound other than said volume expansion compound.

28. The volume type hologram recording photosensitive medium according to claim 26, wherein said photo-curable volume expansion compound in said volume type hologram layer is represented by the following chemical formula (1). 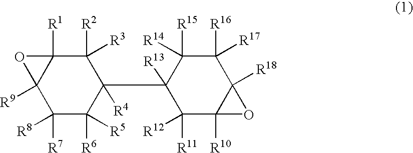
(In the chemical formula, R¹˜R¹⁸ are hydrogen atoms, halogen atoms, alkyl group or alkoxy group, in the case of alkyl group or alkoxy group, oxygen atoms or halogen atoms or a substituent group may be included. Also, R¹˜R¹⁸ may each be the same or different.)

29. The volume type hologram recording photosensitive medium according to claim 27, wherein said photo-curable volume expansion compound in said volume type hologram layer is represented by the following chemical formula (1). 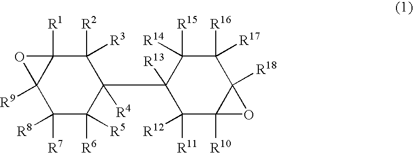
(In the expression, R¹˜R¹⁸ are hydrogen atoms, halogen atoms, alkyl group or alkoxy group, in the case of alkyl group or alkoxy group, oxygen atoms or halogen atoms or a substituent group may be included. Also, R¹˜R¹⁸ may each be the same or different.)

30. The volume type hologram recording photosensitive medium according to claim 26, wherein said photo-curable volume expansion compound in said volume type hologram layer is represented by the following chemical formula (2). 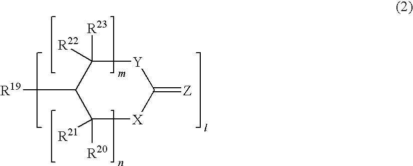
(In the chemical formula, R²⁰˜R²³ are hydrogen atoms, halogen atoms, alkyl group or alkoxy group, in the case of alkyl group or alkoxy group, oxygen atoms or halogen atoms or a substituent group may be included. Also, R²⁰˜R²³ may each be the same or different. l is an integer number between 1˜6, m and n are integer numbers between 0˜3. X, Y and Z are oxygen atoms or sulphur atoms. R¹⁹ represents hydrogen atoms, polyfunctional alkyl in which the carbon number is 1˜10, alkyl ester or alkyl ether.)

31. The volume type hologram recording photosensitive medium according to claim 27, wherein said photo-curable volume expansion compound in said volume type hologram layer is represented by the following chemical formula (2) shown below. 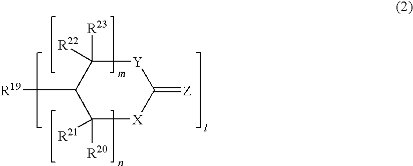
(In the chemical formula, R²⁰˜R²³ are hydrogen atoms, halogen atoms, alkyl group or alkoxy group, in the case of alkyl group or alkoxy group, oxygen atoms or halogen atoms or a substituent group may be included. Also, R²⁰˜R²³ may each be the same or different. l is an integer number between 1˜6, m and n are integer numbers between 0˜3. X, Y and Z are oxygen atoms or sulphur atoms. R¹⁹ represents hydrogen atoms, polyfunctional alkyl in which the carbon number is 1˜10, alkyl ester or alkyl ether.)

32. The volume type hologram recording photosensitive medium according to claim 26, wherein said volume type hologram material layer further includes a binder resin.

33. The volume type hologram recording photosensitive medium according to claim 27, wherein said volume type hologram material layer further includes a binder resin.

34. The volume type hologram recording photosensitive medium according to claim 26, wherein said volume type hologram material layer further includes a sensitizing dye.

35. The volume type hologram recording photosensitive medium according to claim 27, wherein said volume type hologram material layer further includes a sensitizing dye.

36. The volume type hologram recording photosensitive medium according to claim 28, wherein said volume type hologram material layer further includes a sensitizing dye.

37. The volume type hologram recording photosensitive medium according to claim 29, wherein said volume type hologram material layer further includes a sensitizing dye.

38. The volume type hologram recording photosensitive medium according to claim 30, wherein said volume type hologram material layer further includes a sensitizing dye.

39. The volume type hologram recording photosensitive medium according to claim 31, wherein said volume type hologram material layer further includes a sensitizing dye.

40. The volume type hologram recording photosensitive composition according to claim 26, wherein said volume expansion compound in said volume type hologram material layer is included at the ratio of 1 to 90 pts. wt. in the case where the total weight of said volume type hologram material layer is 100 pts. wt.
